(19) United States
(12) Patent Application Publication
(10) Pub. No.: US 2026/0243819 A1
(43) Pub. Date: Aug. 20, 2026

(54) A new type of pre-conditioning tray for testing electronic components

(71) Applicant: Microtest S.p.A., Vicopisano (IT)

(72) Inventor: Giuseppe Amelio, Lucca (IT)

(21) Appl. No.: 19/114,607

(22) PCT Filed: Oct. 18, 2023
(86) PCT No.: PCT/IB2023/060515

§ 371 Date: Mar. 24, 2025

(30) Foreign Application Priority Data
Oct. 20, 2022 (IT) 102022000021681

(51) Int. Cl. G01R 31/28

(52) U.S. Cl. CPC G01R 31/2867; G01R 31/2891

(57) ABSTRACT

A surface for a tray adapted to accommodate electronic components to be tested is nanostructured so as to develop self-adhesive properties.

### SCOPE OF THE INVENTION

The present invention concerns the technical field inherent to the systems for testing electronic components.

In particular, the invention refers to an innovative system that allows a stable positioning of the electronic object to be tested in its tray, for example inside the pre-conditioning area.

The invention also refers to a method for realizing said system.

### A BRIEF OUTLINE OF THE PRIOR ART

The tests of electronic components are essential to verify the correct functioning of an electronic component in its production phase.

The tests can be of various type depending on the function that the electronic component will perform.

For example, temperature tests may be provided in which the electronic component to be tested is subjected to extreme temperature conditions (e.g., from 90° C. to 200° C.).

In this regard, there is already a European publication in the name of the same Applicant, namely EP 3 830 590 A1.

This publication describes a machinery for carrying out such temperature tests and therefore describes a pre-conditioning zone where the components, for example the chips, are parked in a preliminary phase, before being transferred to the test zone.

In the pre-conditioning zone the electronic components are stored in a tray and kept in said position in a temperature condition that is close to the one of the test (for example ±10% with respect to the target).

In this way, the electronic component to be tested undergoes a conditioning close to the test conditions.

It is clear that the electronic component to be tested, for example a chip, must be moved in order to bring it to the test zone and must be positioned in the correct position and then removed at the end of the test.

Therefore, as described in EP 3 830 590, there are said pre-conditioning zones where the component to be tested is kept for a certain time in a special tray in order to be subject to a condition that is close to the one to be tested. If, for example, the test is a temperature test, the pre-conditioning places the component for a certain time at a temperature close to the one of the actual test (as described above) in such a way as to “condition” the component.

That said, the various components to be tested are therefore placed in a pre-conditioning chamber inside a collection tray.

Unfortunately, because of the various vibrations that can arise during the test, the components can move inside the tray losing their original position that was assigned to them.

This creates several technical problems, such as, for example, damage to the components or loss of the order with which they were arranged.

In particular, the displacement, caused by the vibrations, can lead to an error in the subsequent handling of the component to be tested, with consequent possible machine blockage which, in turn, is the cause of long machine downtimes, requires the intervention of the operator and implies an increase in costs due to the decrease in productivity.

The robotic arms, in fact, are programmed to move according to pre-determined coordinates that coincide with the positioning of the components to be tested in the tray.

If the component(s) lose(s) its/their position it is clear that the robotic arm is no longer able to properly grasp the component and this implies an alarm resulting in a machine blockage.

### SUMMARY OF THE INVENTION

It is therefore an object of the present invention to provide an innovative system that solves the aforesaid technical drawbacks.

In particular, it is an object of the present invention to provide a tray surface, possibly applicable to a pre-existing tray, which solves the aforesaid technical drawbacks.

It is also an object of the present invention to provide a tray surface, the tray and relative realization method of the same, which has structural characteristics such as to solve the aforesaid technical drawbacks, thus being equipped with an anti-slip surface.

More in particular, it is an object of the present invention to provide a tray surface, a tray and relative realization method that allow a stable positioning of the component to be tested while minimizing its accidental displacements due to vibrations or other factors, thus ensuring the correct position.

These and other objects are achieved with the present surface adapted to accommodate electronic components (100) to be tested, in accordance with claim 1.

This surface (2, 23) is characterized in that it has self-adhesive properties through the nanostructures it is composed of.

In this way, by realizing a nanostructured surface, it acquires particularly high adhesion characteristics, thereby achieving all the set purposes.

Advantageously, for this purpose, said surface can be constituted by a material selected from the group comprising one or more materials among iron, aluminum, metal alloys, Other similar materials or derivatives thereof.

Advantageously, the self-adhesive properties can be conferred through a surface treatment or a chemical or mechanical attack that generate said nanostructured surface.

In any case, the processings carried out are such as to cause the formation of a nanostructured type surface.

For example, advantageously, the aforesaid surface treatment can be carried out through a galvanic growth process and/or a lithographic process, possibly combined together or not.

The lithographic process also contributes to generating this nanostructured surface.

Alternatively or in combination with the above, a processing of the surface can be provided, in order to obtain its nanostructuring, through a chemical and/or mechanical attack which, as said, can possibly be carried out in combination with the galvanic growth and/or the lithographic process.

An object of the present invention is furthermore also a tray for accommodating electronic components (100) to be tested, characterized in that it comprises a surface (2, 23) in accordance with one or more of the characteristics indicated above and on which in use the electronic components (100) to be tested are placed.

The rest surface of the objects relative to said tray is therefore a nanostructured surface.

Advantageously, the aforesaid surface (2, 23) can be formed by a plurality of surface portions (20), each surface portion (20) comprising a frame (21) that surrounds a self-adhesive surface (23).

There is therefore, in each portion, a nanostructured area on which to rest the component and a surrounding frame.

In this way, predefined positions are defined and each portion is separated from the other through the frame that surrounds the anti-slip zone.

Advantageously, the aforesaid surface portions (20) are approachable to one another within the tray so as to constitute a continuous rest surface.

Each portion represents a positioning zone for the component.

Advantageously, fixing means for fixing the frame (21) to a support plane arranged in the tray, preferably with a removable connection, for example with screws, are comprised.

An object of the present invention is also a method for the realization of a rest surface with self-adhesive properties, in order to support and hold in place one or more electronic components to be tested.

More in particular, an object of the invention is also a method for the realization of a rest surface with self-adhesive properties, said method comprising the realization of a rest surface in such a way that it is of the nanostructured type.

Advantageously, the aforesaid method may comprise the following steps:
Realization of a surface, preferably of a metallic material, as described above;
Processing of the aforesaid surface according to at least one of the following possibilities:
   A) Galvanic type growth, possibly combined or not with a lithographic type processing, or
   B) chemical treatment;
   C) mechanical treatment;
      thus obtaining, in accordance with the possibilities A), B), C) indicated above, nanostructures directly on the surface itself.

Advantageously, said nanostructures can be made of aluminum alloys, ferrous alloys or other materials suitable for the desired purpose, possibly even with the addition or not of polymeric materials suitable for the purpose.

Advantageously, in the case of galvanic growth, one or more layers of a further metallic material with a suitable chemical composition can be deposited on the surface, as described in the previous description.

An object of the present invention is therefore also the use of a nanostructured surface or of a tray provided with such a nanostructured surface in accordance with one or more of the above characteristics in order to conduct a temperature test on one or more electronic components.

A further object of the present invention is therefore also a method for conducting a temperature test on one or more electronic components (100) which provides for the following steps:

Arrangement of the component(s) to be tested on a rest surface in a pre-conditioning zone;

Transfer of the component(s) (preferably via robotic arm) which pick up the component(s) from the pre-conditioning zone to transfer it/them to the test zone.

In accordance with this method, the pre-conditioning zone is provided with a rest surface for the component(s) which is a nanostructured surface in such a way as to acquire self-adhesive properties.

In this way, the component(s) are not subject to unwanted translations with respect to the rest plane on which they are located.

For example, a tray provided with such a surface with self-adhesive properties and on which the component(s) are arranged can be provided in the pre-conditioning zone.

### BRIEF DESCRIPTION OF THE DRAWINGS

Further features and advantages, according to the invention, will become clearer with the following description of some embodiments thereof, made by way of non-limiting example with reference to the appended drawings, in which:

FIG. 1 shows an axonometric of a tray in accordance with the invention containing a surface 2 capable of preventing or reducing the translation of the objects to be tested 100 placed on it;

FIG. 2 shows in section the tray shown in axonometric view of FIG. 1, to better show its structural characteristics, thus highlighting the surface 2 mentioned above and on which the electronic objects 100 to be tested (for example chips) rest;

FIG. 3 shows the single surface 2 formed by a plurality of individual surfaces 20, for example rectangular, placed side by side similarly to a puzzle;

FIG. 4 is a further axonometric view of the tray as a whole;

FIG. 5 shows the single surface 20 and its structure which is described in detail below.

### DESCRIPTION OF SOME PREFERRED EMBODIMENTS

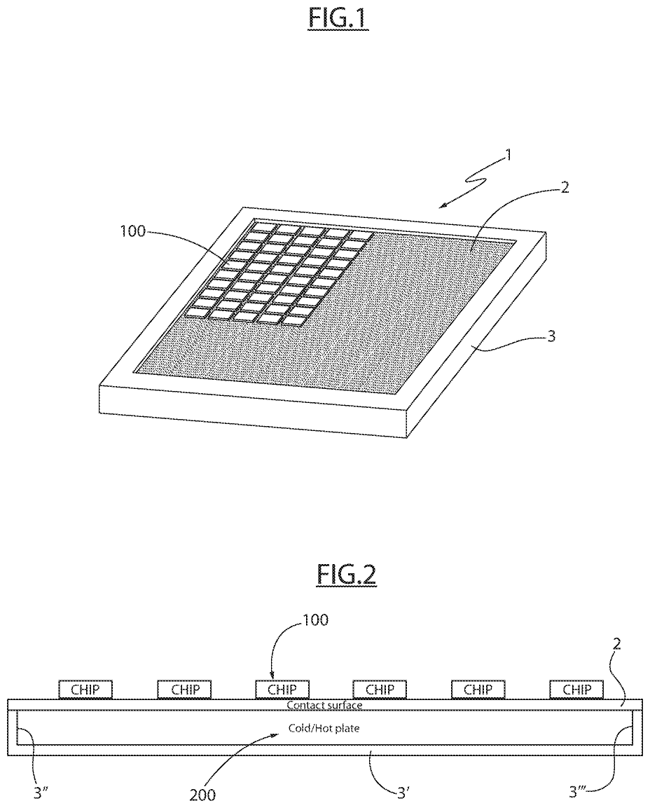

FIG. 1 shows a tray object of the invention.

The tray may have any shape in plan, for example, square or rectangular.

The tray is therefore generally box-shaped, as shown in FIG. 1 and is formed by a box-shaped element 3 provided above with the surface 2 object of the invention.

More in particular, with reference to FIG. 2, the tray comprises a base 3′ and side walls 3″ rising from the base 3′, preferably orthogonally therefrom.

This generates the box-shaped element that houses the further components described below.

In particular, the surface 2 that closes the opening delimited by the side walls and on which the components to be tested 100 rest is comprised.

The components to be tested are preferably electronic components 100 (e.g., electronic chips).

The surface 2, as better described below, has a Self-adhesive effect such that it blocks and/or in any case retains the components to be tested in the direction of the sliding motion on it, thus avoiding or considerably reducing a slipping thereof with respect to the surface 2 itself.

As shown in FIG. 2, below the surface 2, therefore in the compartment of the tray 3 (i.e. in the space delimited by the side walls 3″, the base 3′ and the surface 2), a chamber 200 is generated.

In this chamber, the means used to generate the hot-cold thermal conditions can be arranged.

For example, there may be electrical resistors, or pipes of a hot and/or cold fluid to heat and/or cool the aforesaid chamber 200.

In this way the required thermal conditions are generated which are transferred to the electronic components 100 to be tested that are placed on the surface 2.

It is clear that in a variant of the invention the tray could be without such means as the environmental conditions are generated by other means external to the tray.

However, the solution with the means for generating the desired temperature integrated in the tray is a preferred solution as it simplifies the testing machinery by allowing a heat pre-treatment through the tray itself.

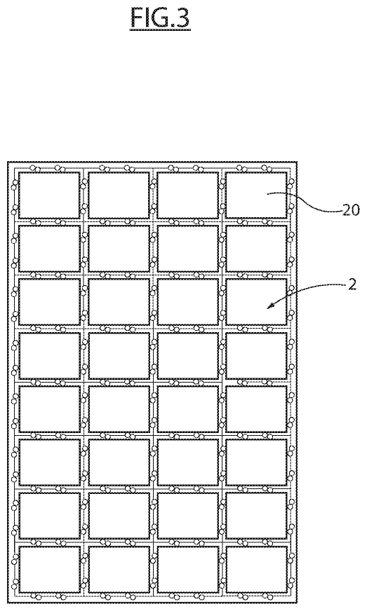

The surface 2, having such self-adhesive characteristics, is shown in an isolated manner in FIG. 3.

It may be a continuous surface, as exemplarily illustrated in FIG. 1.

In a preferred variant of the invention, shown precisely in FIG. 3, it can be constituted by a plurality of surface portions 20 that are approached to one another so as to form the surface 2 as a whole (as a sort of puzzle).

More in particular, FIG. 5 shows a possible structure of the surface portion 20.

It may comprise a frame 21 provided with holes 22 for fixing (for example through screws or inserts or other connection means in general) to an underlying support plane (not shown in the figures for simplicity's sake).

The frame then surrounds the surface 23 which represents the surface with said self-adhesive characteristics.

Said surface 23 of FIG. 5, as well as the continuous surface 2 of FIG. 1, consists of a metallic material selected, for example, from: iron, aluminum, various metal alloys or other substantially similar materials.

De facto, therefore, each surface portion 20 may represent a seat or a station for an electronic component to be tested.

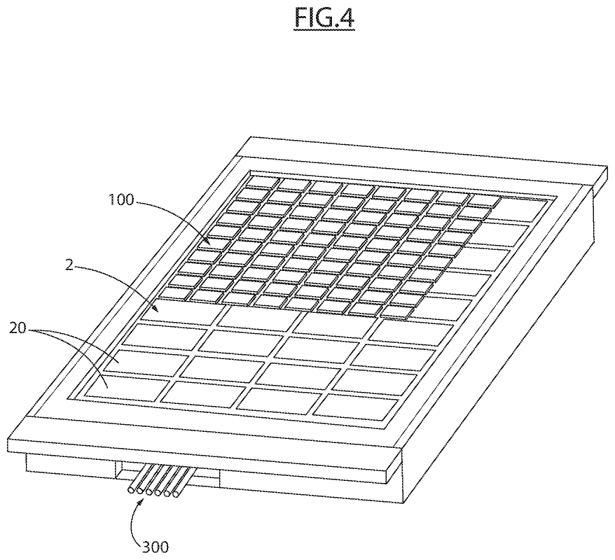

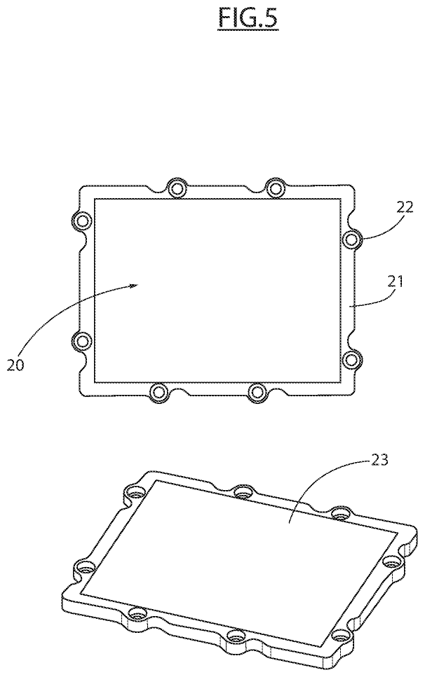

However, each portion 20 may also support more than one electronic component (depending on its size), like for example illustrated in FIG. 4.

The shape of each portion 20, therefore, can be any but it is preferably of the rectangular or quadrangular type although shapes such as circular or any other shape are possible.

Each portion approaches the other, creating, as a whole, the surface 2 as if it were a puzzle.

The advantage of realizing approachable portions is that each portion is clearly visible to the user (for example due to the frame 21) and therefore represents an excellent reference for the user in order to correctly arrange each component to be tested within the area defined by the anti-slip surface 23.

FIG. 4 thus shows the tray 1 as a whole in an axonometric view to show the conduits 300 that can be used to inject for example a hot or cold fluid for the pre-conditioning inside the chamber 200.

It is then highlighted the surface 2 formed in this case by a plurality of portions 20 each having the self-adhesive surface portion 23 and with said portions approached to one another in accordance with FIG. 5.

As mentioned, one could also have a single continuous surface with said self-adhesive properties.

The surface 23 is able to house and hold in place, with a considerable reduction of slipping risks, any type of device 100, preferably an electronic device, thanks to the self-adhesive effect of said surface.

In accordance with the invention, said surface with self-adhesive properties is nanostructured and the self-adhesive properties are obtained thanks to said nanostructure.

More in particular, in accordance with all the configurations described, the retaining effect (self-adhesive) can be obtained through a surface treatment of the surface itself or even a chemical or mechanical attack on it.

The possible treatment, described below, is aimed at obtaining a nanostructured surface in order to obtain the aforesaid self-adhesive characteristics.

More in particular, for example, on each sector 23 (also called portion as indicated above) a process of surface micro-processing is performed in order to obtain the self-adhesive characteristics.

The same obviously applies in the case of a single continuous surface.

In a first possible embodiment of the invention, for example, the self-adhesive surface 23 (or any continuous surface) can be realized through a galvanic type growth, possibly combined with a lithographic type processing.

In the case of galvanic growth, one or more layers of a metallic material with a suitable chemical composition will be deposited on the surface in question.

For example, in said case of galvanic growth, one or more layers of a metallic material consisting of aluminum alloys or ferrous alloys or other types of similar mixed alloys, useful for the desired purpose, may be deposited on the surface in question.

In turn, the lithographic process serves to better define the geometry of the galvanically grown metallic nanostructures: by suitably exposing a resist or the like, by adopting the known maskless technique, or by using jigs and the like, the desired geometry is obtained in which the nanostructure will be grown.

It is recalled here that a nanostructure, as well known per se in the state of the art, is a crystalline, ceramic or metallic structure, characterized by extremely small dimensions (of the order of nanometres) and by electrical, magnetic and mechanical properties different from those of the same materials with normal structure.

The nanostructure, in this case, precisely thanks to its micro-dimensions generates a surface that favours the self-adhesive effect.

Alternatively, the nanostructure (metallic or even of another suitable desired material not necessarily metallic) to be applied on the surface of the tray can be obtained by using a suitable mould, always obtained, as is known, by galvanic growth and/or by means of a lithographic type process.

Alternatively, the self-adhesive surface can be obtained by chemical or mechanical treatment of the starting surface (not necessarily metallic), obtaining the nanostructures directly on the surface itself.

These nanostructures can be made of aluminum alloys, ferrous alloys or other suitable materials suitable for the desired purpose, for example also with the addition of suitable polymeric materials.

The above described with regard to the realization method is equally valid also in the case of continuous surface and not in the form of portions 23 that are approachable to one another.

Thus, a further object of the invention is the method described above for the realization of the aforesaid self-adhesive surface.

In accordance with the method, the realization of the rest surface with self-adhesive properties can be obtained in accordance with the following steps:

Firstly, it is proceeded with the realization of a surface that may preferably but not necessarily be made of a metallic material;

The subsequent step provides a processing in order to transform this surface (and therefore the rest plane it generates) into a nanostructured surface.

The processing of the aforesaid surface can therefore take place according to at least one of the following possibilities:
a) galvanic type growth. This galvanic growth may be possibly combined or not with a lithographic type processing.

The growth must be carried out in such a way as to obtain a nanostructured type coating of the surface. In this sense, any combination of the galvanic process can be combined with a lithographic process.

Chemical treatment directly on the surface or, alternatively, mechanical treatment.

In all the aforesaid cases, nanostructures are realized directly on the surface itself intended to support the electronic component(s) to be tested.

This nanostructured surface feature confers de facto self-adhesive characteristics, greatly increasing the friction that holds the component in place with respect to the surface itself.

Temperature tests can therefore be carried out by placing the component in the pre-conditioning chamber without it undergoing significant displacements.

A method for carrying out a temperature test on one or more electronic components will therefore provide for parking the electronic component(s) to be tested in a pre-conditioning zone which will then be moved to a test zone. In the pre-conditioning zone the components (one or more than one) rest on a rest surface, preferably forming part of a tray.

The rest surface is a surface with non-slip properties based on everything described above.

The present invention therefore also relates to a method for conducting a temperature test on electronic components (100) which provides for the following steps:

Arrangement of the component(s) to be tested on a rest surface in a pre-conditioning zone;

Transfer of the component(s) (preferably via robotic arm) which pick up the component(s) from the pre-conditioning zone to transfer it/them to the test zone.

In accordance with this method, the pre-conditioning zone is provided with a rest surface for the component(s) which is a nanostructured surface in such a way as to acquire self-adhesive properties.

The above described therefore applies to this method introduced here.

For example, it can be provided for a tray provided with such a surface with self-adhesive properties to be arranged in the pre-conditioning zone.

The invention claimed is:

1. A surface for supporting one or more electronic components to be tested, comprising:
said surface made as a nanostructured surface treated to acquire self-adhesive properties.

2. The surface according to claim 1, wherein the surface is made a material selected from one or more of iron, aluminum, a metal alloys alloy, or a derivative thereof.

3. The surface according to claim 1, wherein the self-adhesive properties are developed through a surface treatment or a chemical or mechanical attack that generates said nanostructured surface.

4. The surface according to claim 3, wherein said surface treatment is carried out through a galvanic growth process and/or a lithographic process, combined together or not, or, alternatively or in combination therewith, through a chemical and/or mechanical attack.

5. A tray comprising:
a surface according to claim 1,
wherein the surface is adapted to have electronic components resting thereon.

6. The tray according to claim 5, wherein said surface is formed by a plurality of self-adhesive surface portions, each self-adhesive surface portion being surrounded by a frame.

7. The tray according to claim 6, wherein said surface portions are approachable to one another within the tray so as to constitute a rest surface.

8. The tray according to claim 5, further comprising fixing means for fixing, the frame to a support plane arranged in the tray.

9. A method of producing a rest surface with self-adhesive properties, in order to support one or more electronic components to be tested, said method comprising:
producing a nanostructured rest surface, in such a way that said rest surface acquires self-adhesive properties.

10. The method according to claim 9, further comprising:
producing a surface;
processing said surface according with galvanic growth, combined or not with a lithographic processing and/or chemical or mechanical treatment; and
obtaining nanostructures directly on the surface.

11. The method according to claim 10, wherein, in case of galvanic growth, one or more layers of a further metallic material with a suitable chemical composition are deposited on the surface.

12. The method, according to claim 9, wherein said nanostructured surface comprises nanostructures in aluminum alloys, or ferrous alloys, with or without adding polymeric materials.

13. The method according to claim 9, further comprising a step of producing a tray for supporting one or more components to be tested in a temperature test.
